(19) United States
(12) Patent Application Publication
(10) Pub. No.: US 2021/0066569 A1
(43) Pub. Date: Mar. 4, 2021

(54) ULTRA-THIN THERMOELECTRIC ELEMENTS AND METHOD FOR MANUFACTURING THE SAME

(71) Applicant: KOREA INSTITUTE OF SCIENCE AND TECHNOLOGY, Seoul (KR)

(72) Inventors: Jungjin YOON, Seoul (KR); Seongkwon HWANG, Seoul (KR); Junghwan KIM, Seoul (KR); Hyeonggeun YU, Seoul (KR); Seungjun CHUNG, Seoul (KR); Phillip LEE, Seoul (KR)

(21) Appl. No.: 16/900,998

(22) Filed: Jun. 15, 2020

(30) Foreign Application Priority Data
Aug. 29, 2019 (KR) 10-2019-0106499

(51) Int. Cl. H01L 35/32; H01L 35/24; H01L 35/30; H01L 35/34

(52) U.S. Cl. CPC H01L 35/32; H01L 35/34; H01L 35/30; H01L 35/24

(57) ABSTRACT

An ultra-thin thermoelectric element having a thermoelectric effect includes an ultra-thin substrate, a thermal insulator formed on part of the substrate, and a plurality of active layers formed from a thermoelectric material over the substrate and the thermal insulator, wherein each of the plurality of active layers is connected by an electrode, and an electric current flows due to a temperature difference between the substrate and the thermal insulator.

### CROSS-REFERENCE TO RELATED APPLICATION

This application claims priority to Korean Patent Application No. 10-2019-0106499, filed on Aug. 29, 2019, and all the benefits accruing therefrom under 35 U.S.C. § 119, the contents of which in its entirety are herein incorporated by reference.

### BACKGROUND

### 1. Field

The present disclosure relates to an ultra-thin thermoelectric element and a method for manufacturing the same, and more particularly, to an ultra-thin organic thermoelectric element with minimized heat losses and a method for manufacturing the organic thermoelectric element.

### DESCRIPTION ABOUT NATIONAL RESEARCH AND DEVELOPMENT SUPPORT

This study was supported by the technology development program respond to the climate change of Ministry of Science and ICT, Republic of Korea (Projects No. 1711077390 and 1711087699) under the superintendence of National Research Foundation of Korea.

### 2. Description of the Related Art

A thermoelectric element is an element using an effect resulting from interaction between heat and electricity. A temperature gradient is created across a thermoelectric material in which the current flows, and this is known as Peltier effect, and to the contrary, electricity is generated when there is temperature difference across a thermoelectric material, and this is known as Seebeck effect.

Using the Seebeck effect, heat generated from computers, automobile engines and industrial plants can be converted into electrical energy. Thermoelectric power generation using the Seebeck effect can be used as a new regenerative energy source.

The existing thermoelectric modules are large and heavy, and they can only obtain energy from heat sources having no curves. Recently, with the increasing interest in large-scale thermoelectric elements or wearable thermoelectric elements, there is extensive discussion of polymer thermoelectric materials or flexible thermoelectric materials.

To make use of various types of heat sources including human body, flexible thermoelectric materials are necessary. Inorganic thermoelectric materials have good thermoelectric properties, but they are rigid and prone to breaking, and these drawbacks make it difficult to use in flexible and wearable device applications. In contrast, thermoelectric modules using flexible organic thermoelectric materials are manufactured on flexible and elastic platforms, making it possible to obtain thermal energy from various types of heat sources, and the thermal energy can be used as an energy source for operating wearable sensors.

The flexible organic thermoelectric materials (for example, PEDOT:PSS) have mechanically flexible properties and are easy to implement less harmful, lower-priced and larger-scale thermoelectric elements than thermoelectric inorganics, but in many cases, the thermoelectric conversion efficiency is low due to the manufacturing method.

Accordingly, to manufacture modules using organic thermoelectric materials, it is necessary to optimize the process and structure and improve the performance of the thermoelectric materials, and particularly, minimizing heat losses due to heat absorption by the substrate is essential for organic thermoelectric modules having low thermoelectric efficiency.

### RELATED LITERATURES

### Non-Patent Literatures

(Non-Patent Literature 1) Byung Jin Cho et al., “A wearable thermoelectric generator fabricated on a glass fabric”, Energy Environ. Sci., 2014, 7, 1959-1965.

### SUMMARY

The present disclosure is designed to solve the above-described problem of the related art, and therefore the present disclosure is directed to providing an ultra-thin thermoelectric element in which an organic thermoelectric element is manufactured on an ultra-thin substrate to minimize heat losses by the substrate, and a thermal insulator is interposed through a printing process to create a temperature difference, and a method for manufacturing the same.

To achieve the above-described object, according to an aspect of the present disclosure, there is provided an ultra-thin thermoelectric element having a thermoelectric effect, the ultra-thin thermoelectric element including an ultra-thin substrate, a thermal insulator formed on part of the substrate, and a plurality of active layers formed from a thermoelectric material over the substrate and the thermal insulator, wherein each of the plurality of active layers is connected by an electrode, and an electric current flows due to a temperature difference between the substrate and the thermal insulator.

According to an embodiment of the present disclosure, when the ultra-thin thermoelectric element is worn on a human body, the electric current may flow due to the temperature difference between the plurality of active layers on the substrate in contact with skin and the plurality of active layers on the thermal insulator.

According to an embodiment of the present disclosure, the ultra-thin substrate may be made using a tattoo paper or a sticker.

According to an embodiment of the present disclosure, the plurality of active layers may be made of at least one organic thermoelectric material selected from the group consisting of PEDOT:PSS, PEDOT:Tos, and PANi.

According to an embodiment of the present disclosure, the thermal insulator may be made using PDMS.

According to an embodiment of the present disclosure, the ultra-thin thermoelectric element may further include a protective coating on the plurality of active layers.

According to an embodiment of the present disclosure, the protective coating may be made using an ultra-thin tattoo paper or sticker.

According to another aspect of the present disclosure, there is provided a method for manufacturing the above-described ultra-thin thermoelectric element including forming the thermal insulator on the substrate, forming the plurality of active layers and the electrode on the protective coating, wherein the electrode connects each of the plurality of active layers, placing the protective coating above the substrate such that the plurality of active layers is disposed over the substrate and the thermal insulator, and carrying out suction between the protective coating and the substrate.

The device according to various embodiments of the present disclosure provides an organic thermoelectric element manufactured on an ultra-thin substrate. Through this, it is possible to provide a thermoelectric element with minimized heat losses by the substrate and increased thermoelectric conversion efficiency. Additionally, it is possible to provide a wearable organic thermoelectric element that is non-harmful to human body due to the properties of the organic thermoelectric element and tightly adheres to human body by using the ultra-thin substrate. Moreover, it is possible to provide a method whereby a wearable thermoelectric element with a thermal insulator interposed through a printing process to create a temperature difference is manufactured in an easy and simple manner.

The effects that can be obtained by the present disclosure are not limited to the above-mentioned effects, and other effects not mentioned herein will be clearly understood by one of ordinary skill in the art from the following description.

### BRIEF DESCRIPTION OF THE DRAWINGS

FIG. 1 is a schematic diagram of a thermoelectric element of thermal insulator interposed structure according to an embodiment of the present disclosure.

FIG. 2 shows the working principle of a thermoelectric element of thermal insulator interposed structure according to an embodiment of the present disclosure.

FIG. 3 is a perspective view of an organic thermoelectric element manufactured using an ultra-thin substrate according to an embodiment of the present disclosure.

FIGS. 4A to 4E show a process of manufacturing an organic thermoelectric element using an ultra-thin substrate according to an embodiment of the present disclosure.

### DETAILED DESCRIPTION

The present disclosure may be modified in a variety of different forms and may have many embodiments, and thus it is intended to illustrate particular embodiments in the drawings and specify the particular embodiments in the detailed description. This is not intended to limit the present disclosure to the particular embodiments, and it will be understood that the present disclosure includes all modifications, equivalents or substitutes within the spirit and scope of the present disclosure.

In describing the present disclosure, the use of the terms “first”, “second”, and the like may be used to describe various elements, but the elements may not be limited by the terms. The terms may be only used to distinguish one element from another.

For example, without departing from the scope of protection of the present disclosure, a first element may be designated as a second element, and likewise, a second element may be designated as a first element.

The term “and/or” as used herein may include a combination of relevant items or any of relevant items.

In contrast, it will be understood that when an element is referred to as being “directly connected to” or “directly coupled to” another element, intervening elements are absent.

The terminology used herein is for the purpose of describing particular embodiments only and is not intended to be limiting of the present disclosure. As used herein, the singular forms may include the plural forms as well, unless the context clearly indicates otherwise.

It will be further understood that the term “comprises” or “includes” when used in this specification, specifies the presence of stated features, integers, steps, operations, elements, components or groups thereof, but does not preclude the presence or addition of one or more other features, integers, steps, operations, elements, components or groups thereof.

Unless otherwise defined, all terms (including technical and scientific terms) used herein have the same meaning as commonly understood by one of ordinary skill in the art.

The terms, such as those defined in commonly used dictionaries, should be interpreted as having a meaning that is consistent with their meaning in the context of the relevant art, and will not be interpreted in an idealized or overly formal sense unless expressly so defined herein.

Hereinafter, a wearable organic thermoelectric element using an ultra-thin substrate according to an exemplary embodiment of the present disclosure and a method for manufacturing the same will be described with reference to the accompanying drawings. While the present disclosure is described with reference to the embodiments shown in the drawings, this is described as an embodiment, and the technical spirit of the present disclosure and its essential elements and operation are not limited thereby.

Recently, there is a growing demand for flexible thermoelectric materials and platforms to make use of various types of heat sources. Particularly, many studies have been made on flexible thermoelectric module devices that can be used as an energy source to operate wearable sensors worn on human body.

Inorganic thermoelectric materials have good thermoelectric properties but they are hard and prone to breaking and cause harm to human body, so it is difficult to use them in the wearable applications. In contrast, organic thermoelectric materials (for example, PEDOT:PSS) are mechanically flexible, but have lower thermoelectric efficiency, and due to this drawback, particularly, it is important to minimize heat losses due to heat absorption by the substrate.

Most of earlier studies about wearable thermoelectric elements have been conducted on a plastic substrate having the thickness of 100 μm or more. To increase an amount of power generated by wearable thermoelectric elements, it is essential to minimize heat losses due to heat absorption by the substrate. In general, about 30% of thermal resistance occurs between the skin and the substrate, and to minimize heat losses from the substrate, suggestions have been made to use an ultra-thin substrate that is a few μm in thickness.

An organic thermoelectric element manufactured on an ultra-thin substrate and a method for manufacturing the same will be described with reference to the drawings below.

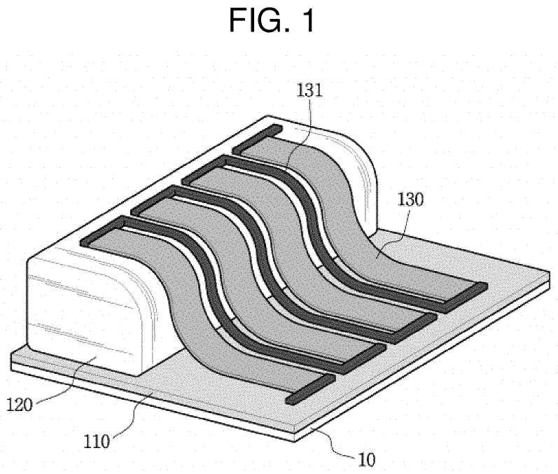

FIG. 1 is a schematic diagram of a thermoelectric element of thermal insulator interposed structure according to an embodiment of the present disclosure.

Referring to FIG. 1, the thermoelectric element includes a plurality of active layers 130 formed on a substrate 110 using a thermoelectric material, and an electrode 131 connecting the active layers 130. In this instance, a thermal insulator 120 may be formed on part of the substrate 110 to create a temperature difference across the active layers 130.

According to an embodiment of the present disclosure, the substrate 110 is manufactured in a very small thickness of a few μm, and may be manufactured of a material and shape that fit tightly to a heat source 10 to minimize heat losses by the substrate 110. For the substrate 110, an ultra-thin tattoo paper or sticker, for example, may be used. The ultra-thin tattoo paper may be a tattoo paper having the thickness of a few μm, for example, about 5 μm. The organic thermoelectric element manufactured on the ultra-thin substrate 110 may minimize heat absorbed by the substrate, and accordingly may increase the thermoelectric efficiency. Additionally, the ultra-thin substrate 110 using the tattoo paper or the sticker is a platform that adheres to human body very tightly in order to transfer from the heat source in close contact without an unnecessary gap, thereby resulting in much higher thermoelectric efficiency.

As shown in FIG. 1, the thermal insulator 120 is interposed on the substrate 110 to create a temperature difference across the active layers 130. According to an embodiment of the present disclosure, the thermal insulator 120 may be formed on part of the substrate 110 through a printing process. The thermal insulator 120 may use a flexible insulating material such as polydimethyl siloxane (PDMS). The thermal insulator 120 may be formed using the insulating material by various printing techniques, for example, spin coating, bar coating, slot die coating, inkjet printing and spray printing. Since the thermal insulator may be interposed by a low temperature process of 100° C. or less without lithography or a high temperature deposition process, the process is suitable for the substrate made from an ultra-thin tattoo paper.

Most of the existing organic thermoelectric elements are manufactured in the parallel direction, and these parallel direction thermoelectric elements are difficult to create a temperature difference across two ends thereof when heat is supplied to produce thermoelectric power. In case that the thermal insulator 120 is interposed to create a temperature difference, when heat generated from the skin of the human body is transferred to the thermoelectric element in contact with the skin, a definite temperature difference occurs between two ends of the element where contact with the skin is made at one end through the ultra-thin substrate 110 and the heat of the skin is seldom transferred to the other end due to the thermal insulator 120. Through this, a sufficient amount of power may be produced from the heat source 10 of the human body, and may be used as an energy source to operate various wearable sensors.

The active layers 130 are where a thermoelectric material is formed. As shown in FIG. 1, the active layers 130 has one end formed on the substrate 110, and the other end placed over the thermal insulator 120, forming a step. The thermoelectric element may include the plurality of active layers formed at a regular interval on one substrate 110 and connected to the electrode 131 as shown in FIG. 1. The thermoelectric material, of which the active layers 130 according to an embodiment of the present disclosure are made, may include organic materials, for example, poly(3,4-ethylenedioxythiophene) (PEDOT)-based materials such as poly(3,4-ethylenedioxythiophene):polystyrene sulfonate (PEDOT:PSS) and poly(3,4-ethylenedioxythiophene):tosylate (PEDOT:Tos), or other organic materials such as polyaniline (PANi). The thermoelectric material is not necessarily limited to the above examples, and in addition to the above-described materials, a variety of other organic materials may be used if necessary. The active layers 130 may be formed using the organic thermoelectric material by various printing techniques, for example, spin coating, bar coating, slot die coating, inkjet printing and spray printing.

For the electrode 131, various materials may be selected, and for example, a silver ink may be applied and used through an inkjet printing process.

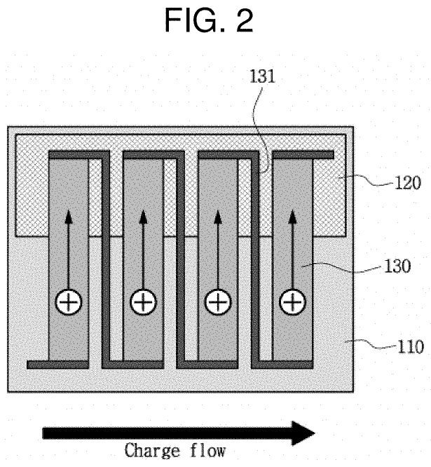

FIG. 2 shows the working principle of the thermoelectric element of thermal insulator interposed structure according to an embodiment of the present disclosure. Referring to FIG. 2, the working principle of the thermoelectric element is shown based on the plane view of the thermoelectric element with the interposed thermal insulator as shown in FIG. 1.

As shown in FIG. 2, when a temperature difference occurs between upper and lower parts on the basis of the drawing, a flow of currents is generated by the movement of electrons. That is, electricity is produced by a temperature difference between the upper and lower parts of the active layer 130. The lower part of the active layers 130 contacts the heat source 10 through the ultra-thin substrate 110, at which temperature is higher, and the upper part of the active layers 130 is formed on the thermal insulator 120 and gets little or no heat from the heat source 10, at which temperature is lower. When a flow of currents is generated in the thermoelectric material due to the temperature difference between the upper and lower parts of the active layers 130, the currents flow in the arrow direction along the electrode 131, and the thermoelectric element operates using the flow of currents as an energy source.

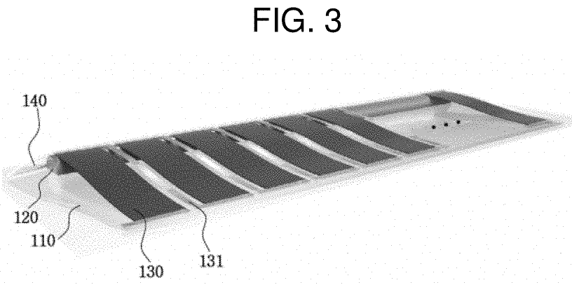

FIG. 3 is a perspective view of the organic thermoelectric element manufactured using the ultra-thin substrate according to an embodiment of the present disclosure.

Referring to FIG. 3, shown is the thermoelectric element manufactured with a very small thickness and a tight fit to human body by placing the thermoelectric material on the ultra-thin substrate 110 using a material such as a tattoo paper.

As shown in FIG. 3, the thermoelectric element may include the thermal insulator 120 formed on the ultra-thin substrate 110, the plurality of active layers 130 formed over the substrate 110 and the thermal insulator 120, the electrode 131 connecting the active layers 130, and a protective coating 140 that covers the active layers 130 to prevent the separation of the components formed on the ultra-thin substrate 110. The protective coating 140 may use a material such as an ultra-thin tattoo paper in the same way as the substrate 110 to easily attach it to the substrate 110 and keep it ultra-thin and tightly fit to human body.

As such, using an ultra-thin thermoelectric platform such as a tattoo paper that has never been used for thermoelectric elements before, it is possible to create a temperature difference with minimized heat losses due to heat absorption by the substrate 110, and thus it is suitable for wearable thermoelectric elements.

Although the ultra-thin thermoelectric element of the above-described structure is described using a tattoo paper or a sticker as an example, the present disclosure is not necessarily limited thereto, any material that can be manufactured with flexibility, a very small thickness and a tight fit to human body may be used to manufacture the thermoelectric element, and in the case of a sticker, when a paper of an adhesive part is removed, an adhesive area is provided and makes it easy to attach to a target site.

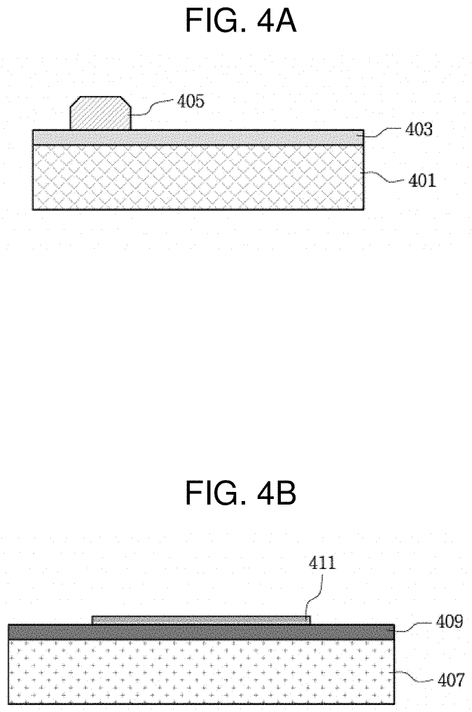

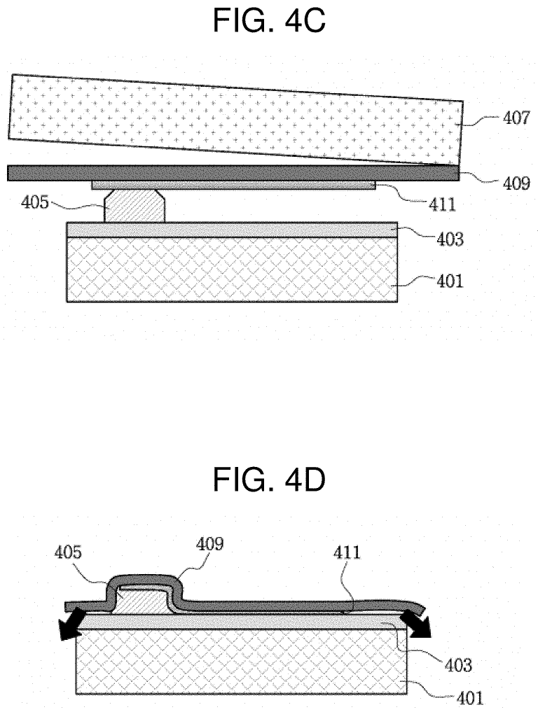

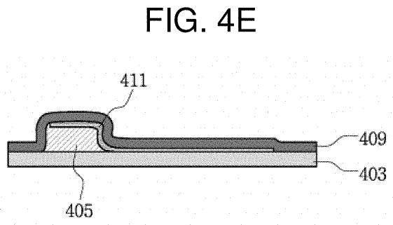

A process of manufacturing a thermoelectric element using a tattoo paper for the substrate 110 and the protective coating 140 according to an embodiment of the present disclosure will be described with reference to FIGS. 4A to 4E.

FIGS. 4A to 4E show a process of manufacturing an organic thermoelectric element using an ultra-thin substrate according to an embodiment of the present disclosure. That is, shown is a cross-sectional view of a process of manufacturing a thermoelectric element having a structure in which a thermal insulator and a thermoelectric material are disposed on an ultra-thin substrate using a tattoo paper as proposed, so that areas having a temperature difference are separately disposed in a 3-dimensional space to provide a thermoelectric effect.

Referring to FIG. 4A, first, shown is a step of forming a thermal insulator 405 on a material having an ultra-thin substrate 403 attached to a donor substrate 401. For example, the ultra-thin substrate 403 may be attached to the donor substrate 401 by an adhesive. The donor substrate 401 facilitates a printing process on the ultra-thin substrate 403, and when the donor substrate 401 is removed later, the ultra-thin substrate 403 may be easily attached to a desired area by the adhesive. After the donor substrate 401 is removed, the ultra-thin substrate 403 is a tighter fit due to the feature. The thermal insulator 405 may be formed on part of the substrate 403 through a printing process of a thermal insulating material as shown in FIGS. 1 to 3. For example, the thermal insulator 405 may be formed by a printing process of a PDMS material, and as the thermal insulator 405 is introduced by this method, it is possible to perform a low temperature process without lithography or a high temperature deposition process, and the process is suitable for the tattoo paper ultra-thin substrate 110. The thermal insulator 405 may be formed using a flexible insulating material by various printing techniques, for example, spin coating, bar coating, slot die coating, inkjet printing and spray printing.

Referring to FIG. 4B, shown is the step of forming an active layer 411 and an electrode (not shown) on a material having a protective coating 409 attached to a donor substrate 407 that is different from the donor substrate 401. Apart from the process of FIG. 4A, this process may be performed on a separate tattoo paper, and for example, the protective coating 409 may be attached to the donor substrate 407 by an adhesive. The donor substrate 407 facilitates a printing process on the ultra-thin protective coating 409, and is removed later. The active layer 411 may be formed on the protective coating 409 through a printing process of an organic thermoelectric material. In this instance, as shown in the plane view of FIG. 2, the plurality of active layers 411 and the electrode connecting them may be formed by a printing process. For example, the active layers 411 may be formed using an organic thermoelectric material by various printing techniques, such as spin coating, bar coating, slot die coating, inkjet printing and spray printing. The organic thermoelectric material allows a solution process, which makes it easy to develop thermoelectric elements using various techniques. The electrode may be formed, for example, by a printing process of an ink.

Referring to FIG. 4C, shown is a step of placing the protective coating 409 above the ultra-thin substrate 403 such that the active layers 411 is disposed over the ultra-thin substrate 403 and the thermal insulator 405. As shown in FIG. 4C, part of the active layers 411 is disposed on the thermal insulator 405 and the remaining part is disposed on the ultra-thin substrate 403, so that the active layers 411 are disposed over both the thermal insulator 405 and the ultra-thin substrate 403. Through this, it is possible to create a temperature difference and obtain a thermoelectric effect. The ultra-thin substrate 403 and the protective coating 409 are brought into close contact with each other, and the donor substrate 407 is removed.

Referring to FIG. 4D, provided is a step of carrying out suction between the ultra-thin substrate 403 and the protective coating 409. It is necessary that the protective coating 409 is attached closely to the ultra-thin substrate 403 to fix and protect the thermal insulator 405 disposed on the ultra-thin substrate 403 and the active layers 411 and the electrode disposed thereon. To this end, a process of carrying out suction between the ultra-thin substrate 403 and the protective coating 409 is performed, and for example, the ultra-thin substrate 403 and the protective coating 409 may be brought into close contact with each other by vacuum suction. Due to the thickness of a few μm, it is easy to bring the ultra-thin substrate 403 and the ultra-thin protective coating 409 into close contact with each other, but the protective coating 409 may have an adhesive applied thereto.

Referring to FIG. 4E, shown is a step of bringing the ultra-thin substrate 403 and the protective coating 409 into close contact with each other and removing the donor substrate 401. Shown is the thermoelectric element completed by carrying out suction between the ultra-thin substrate 403 and the protective coating 409 and removing the donor substrate 401. The resulting thermoelectric element also has an ultra-thin feature between a few μm and a few tens of μm except the thermal insulator 405 part. The ultra-thin thermoelectric element itself may tightly fit to the heat source 10 such as skin, but after the donor substrate 401 is removed, the adhesive may remain on the surface of the ultra-thin substrate 403, and through this, the ultra-thin thermoelectric element may be adhered to the heat source 10 more easily.

In addition to the above-described method, the thermoelectric element of FIG. 4E may be manufactured by a variety of other methods. As the thermoelectric material is disposed over the thermal insulator by using the ultra-thin substrate, it is possible to separate HOT zone by the heat source from COLD zone by the thermal insulator in three dimensions, and minimize heat losses due to heat absorption by the ultra-thin substrate. Through this, it is possible to implement efficient thermoelectric elements and provide thermoelectric elements suitable for wearable applications.

In the above-described particular embodiments, the elements included in the present disclosure are represented in singular or plural form according to the presented particular embodiments. However, for convenience of description, the singular or plural form is suitably selected in the presented context, and the above-described embodiments are not limited to single or multiple elements, and a certain element represented in plural form may be a single element, and a certain element represented in singular form may be multiple elements.

While particular embodiments of the present disclosure have been described, it is obvious that many modifications may be made thereto without departing from the scope of technical spirit set forth in various embodiments. Therefore, the present disclosure should not be construed as limited to the disclosed embodiments, and should be defined by the appended claims and their equivalents.

What is claimed is:

1. An ultra-thin thermoelectric element having a thermoelectric effect, the ultra-thin thermoelectric element comprising:
an ultra-thin substrate;
a thermal insulator formed on part of the substrate; and
a plurality of active layers formed from a thermoelectric material over the substrate and the thermal insulator,
wherein each of the plurality of active layers is connected by an electrode, and an electric current flows due to a temperature difference between the substrate and the thermal insulator.

2. The ultra-thin thermoelectric element according to claim 1, wherein when the ultra-thin thermoelectric element is worn on a human body, the electric current flows due to the temperature difference between the plurality of active layers on the substrate in contact with skin and the plurality of active layers on the thermal insulator.

3. The ultra-thin thermoelectric element according to claim 1, wherein the ultra-thin substrate is made using a tattoo paper or a sticker.

4. The ultra-thin thermoelectric element according to claim 1, wherein the plurality of active layers is made of at least one organic thermoelectric material selected from the group consisting of PEDOT:PSS, PEDOT:Tos, and PANi.

5. The ultra-thin thermoelectric element according to claim 1, wherein the thermal insulator is made using PDMS.

6. The ultra-thin thermoelectric element according to claim 1, further comprising:
a protective coating on the plurality of active layers.

7. The ultra-thin thermoelectric element according to claim 6, wherein the protective coating is made using an ultra-thin tattoo paper or sticker.

8. A method for manufacturing the ultra-thin thermoelectric element defined in claim 7, the method comprising:
forming the thermal insulator on the substrate;
forming the plurality of active layers and the electrode on the protective coating, wherein the electrode connects each of the plurality of active layers;
placing the protective coating above the substrate such that the plurality of active layers is disposed over the substrate and the thermal insulator; and
carrying out suction between the protective coating and the substrate.
